(19) United States
(12) Patent Application Publication
(10) Pub. No.: US 2025/0105943 A1
(43) Pub. Date: Mar. 27, 2025

(54) REDUCING STARTUP TIME OF A TRELLIS-BASED MLSE DECODER

(71) Applicant: Microchip Technology Incorporated, Chandler, AZ (US)

(72) Inventors: Peter Graumann, Calgary (CA); Fan Yang, Burnaby (CA)

(21) Appl. No.: 18/892,276

(22) Filed: Sep. 20, 2024

Related U.S. Application Data
(60) Provisional application No. 63/584,462, filed on Sep. 21, 2023.

(51) Int. Cl. H04L 1/00; H03M 13/39

(52) U.S. Cl. CPC H04L 1/0054; H03M 13/3955; H04L 1/006

(57) ABSTRACT

A method may include at least partially initializing a trellis of an SE engine at least partially based on predetermined state information about a communication channel associated with an incoming data stream; and processing, via the MLSE engine, the incoming data stream to further initialize the trellis and decode the incoming data stream.

### CROSS-REFERENCE TO RELATED APPLICATION

This application claims the benefit under 35 U.S.C. § 119 (e) of U.S. Provisional Patent Application Ser. No. 63/584,462, filed Sep. 21, 2023, the disclosure of which is hereby incorporated herein in its entirety by this reference.

### FIELD

One or more examples relate to trellis-based signal processing including encoding and decoding. Some examples relate to techniques to reduce complexity of Maximal Likelihood Sequence Estimation (MLSE), and more specifically, reducing startup time of a trellis-based MLSE decoder.

### BACKGROUND

Various signaling techniques are used in normal and high-speed serial communication systems. Examples include modulation schemes such as Non-Return to Zero (NRZ), Pulse Amplitude Modulation 2 (PAM2), and PAM4.

### BRIEF DESCRIPTION OF THE DRAWINGS

To easily identify the discussion of any particular element or act, the most significant digit or digits in a reference number refer to the figure number in which that element is first introduced.

FIG. 1 illustrates an example process according to a general method to initialize a trellis, in accordance with one or more examples.

FIG. 2 is a block diagram depicting a pipeline architecture of a windowed MLSE process that utilizes predetermined state information to at least partially initialize a trellis of an MLSE engine, in accordance with one or more examples.

FIG. 3 is a functional block diagram of a pipeline architecture depicting a process to initialize a trellis of an MLSE engine, in accordance with one or more examples.

FIG. 4 is a block diagram depicting pipeline architecture of a decoder that utilizes predetermined state information to at least partially initialize a trellis of an MLSE engine before decoding a received sequence of symbols, in accordance with one or more examples.

FIG. 5 is a block diagram of circuitry that, in some examples, may be used to implement various functions, operations, acts, processes, or methods disclosed herein.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments may be utilized, and structural, material, and process changes may be made without departing from the scope of the disclosure.

The illustrations presented herein are not meant to be actual views of any particular method, system, device, or structure, but are merely idealized representations that are employed to describe the embodiments of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawing could be arranged and designed in a wide variety of different configurations. Thus, the following description of various embodiments is not intended to limit the scope of the present disclosure, but is merely representative of various embodiments. While the various aspects of the embodiments may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the embodiments disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer executes computing instructions (e.g., software code) related to embodiments of the present disclosure.

The embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, any relational term, such as “over,” “under,” “on,” “underlying,” “upper,” “lower,” without limitation, is used for clarity and convenience in understanding the disclosure and accompanying drawings and does not connote or depend on any specific preference, orientation, or order, except where the context clearly indicates otherwise.

In this description, the term “coupled” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The term “connected” may be used in this description interchangeably with the term “coupled,” and has the same meaning unless expressly indicated otherwise or the context would indicate otherwise to a person having ordinary skill in the art.

A convolutional coder (or decoder) is a finite state machine (FSM) with a limited amount of state (e.g., limited number of states). A convolutional coder produces output bits that are various functions of input bits and the previous state. After the output bits are produced, the FSM transitions to a new state based on the input bits and the previous state of the convolutional coder. In the case of a convolutional decoder, the decoder considers a received sequence of bits and determines an input sequence of bits that best (most likely) explains the received sequence of bits. Stated another way, the decoder determines an input sequence of bits (i.e., an input sequence of bits fed to the convolutional coder) that most likely produced the received sequence of bits.

A trellis is a graphical representation of the FSM of the convolutional coder (or decoder) that illustrates the state transitions of the convolutional coder over time. The trellis includes a first set of nodes (typically depicted as circles) that represent possible states at a current time step, a second set of nodes that represent possible states at a next time step, and arcs (depicted as arrows) that connect nodes in the first set to nodes in the second set. Each node represents a specific state (e.g., identified by a number). Each arc represents a valid transition from one state to another state. Using a trellis representative of the convolutional coder, a decoder only has to consider the finite number of possible states, and the most likely sequence that led to that state, using an algorithm such as the Viterbi algorithm.

A convolutional coder can be used by a transmitter to produce encoded output bits that are a function of a current input bit and one or more previous input bits that set the coder's current state. This effectively spreads the information of an input bit (the current input bit) over several output bits, which increases redundancy and the ability of a receiver to detect and correct errors that may occur during transmission. The redundancy introduced by convolutional encoding allows a transmitted signal to be more resilient to the impairments of the channel, such as noise, insertion loss, and interference. The encoded output bits may be modulated onto a carrier using a modulation scheme, i.e., encoded output bits are mapped to physical symbols that are transmitted on a physical medium (the transmitted symbols).

Pulse amplitude modulation (PAM) is a modulation technique that encodes data by varying amplitude of electrical pulses using multiple distinct signal levels.

In binary signaling techniques, such as PAM2 or non-return to zero (NRZ), two voltage levels represent a symbol, and each symbol may represent 1 bit of data. For example, a first voltage level of a PAM2 symbol may represent a ‘0’ and second, different voltage level of a PAM2 symbol may represent a ‘1.’

PAM4 is a signaling technique typically used to transmit data over high-speed serial communication links, such as high-speed Serializer/Deserializer (SerDes) communication systems (“high-speed SerDes”) found in high-speed communication systems such as data centers, networking equipment, and high-speed interfaces such as PCIe (Peripheral Component Interconnect Express) and USB (Universal Serial Bus).

PAM4 uses four voltage levels to represent a symbol. A PAM4 symbol may encode 2 bits of data, which allows higher data rates (e.g., as compared to PAM2 signaling) without the need for increasing the signaling frequency. The voltage levels in PAM4 are typically represented as −3, −1, +1, and +3 (or 1, −1/3, +1,3, +1) or a similar combination. For symbol recovery, a decoder determines the amplitude of the incoming signal (signal level) and maps the determined signal level to data.

Using PAM4, a SerDes can transmit 2 bits of data per symbol, effectively doubling the data rate compared to binary signaling techniques. However, PAM4 signaling is more complex than PAM2 and sensitive to noise, channel impairments, and inter-symbol interference (ISI) that are found in high-speed SerDes channels. So, sophisticated equalization and signal processing techniques are used to achieve reliable communication at high data rates, for example, to achieve target symbol error rates (SER) expected in high-speed SerDes, without limitation. Despite its challenges, PAM4 has become widely adopted in modern high-speed communication interfaces to meet the increasing demand for higher data transfer rates while maintaining a manageable level of complexity and power consumption.

When a PAM4 signal is transmitted through a communication channel, it can experience various forms of distortion, leading to the possibility of errors during data recovery. ISI is a form of distortion that occurs when the symbols from neighboring bits interfere with each other due to channel characteristics, which can cause confusion during decoding.

Decision Feedback Equalization (DFE) is a technique used in SerDes decoders to combat the various forms of distortion that occur in high-speed SerDes channels.

Decision Feedback Equalization (DFE) is a signal processing technique used at the receiver end of a communication link, especially in SerDes decoders, to mitigate intersymbol interference (ISI) and other distortions in high-speed communication links. DFE operates based on feedback: decisions made by the decoder for previous symbols are used to reduce (e.g., cancel out, without limitation) ISI for the current symbol.

By way of example of a DFE process: a received signal is sampled, and a preliminary decision is made about a current transmitted symbol (a “symbol decision”) based on the sampled signal. This preliminary decision may be affected by ISI from previously transmitted symbols. The decoder uses the decisions from previously decoded symbols to estimate their ISI contributions to the received signal. These estimated contributions are subtracted from the current sample to cancel or reduce ISI. The decoder then makes a more accurate decision about the current transmitted symbol. The decoder continues to use this process, with feedback information improving the accuracy of subsequent symbol decisions, thereby enhancing overall data recovery.

DFE is used in PAM4 receivers to recover transmitted data from the received signal. In some channels, DFE alone is sufficient to suitably mitigate ISI and recover the transmitted data accurately. However, as the channel becomes more challenging, especially with higher insertion loss, DFE may become insufficient.

For such difficult channels, Maximal Likelihood Sequence Estimation (MLSE) is sometimes used instead of DFE. MLSE is a signal processing technique that can provide a more robust solution than DFE by considering multiple symbol sequences and selects the one it determines has the highest likelihood of being the transmitted sequence, thus offering better handling of severe ISI and channel impairments. MLSE evaluates these sequences by considering the received signal, channel characteristics, and statistical properties of the transmission.

In general, MLSE can provide one to two decades of improvement in receiver SER compared to DFE, but at a significant cost in terms of implementation area and power consumption. As data rates increase (e.g., 112 Gbps, 128 Gbps, 224 Gbps), MLSE becomes more important for reducing symbol error rate (SER). Traditional MLSE algorithms are computationally intensive and require knowledge of the channel characteristics, noise statistics, and the modulation scheme used. They often employ Viterbi-like algorithms or other optimization methods to efficiently explore the vast number of possible symbol sequences and determine the most probable one.

An MLSE algorithm uses channel state information (CSI) to find the most likely transmitted symbol or sequence of symbols given a received signal. CSI is information about the characteristics and/or condition of a communication channel via which a signal is transmitted. CSI may be determined or pre-determined, and may include one or more of:
Signal-to-Noise Ratio (SNR): The ratio of the signal power to the noise power in the received signal.
Channel Response: The frequency response of the channel, which indicates how the channel affects different frequency components of the transmitted signal.
Impulse Response: The time-domain response of the channel, indicating how the channel introduces delays and distortions to the transmitted signal.
Channel Memory: The extent to which the channel retains information about past transmitted symbols, which influences ISI.
Modulation Scheme: The type of modulation used, which affects the mapping of symbols to signal points.

In PAM4, MLSE is applied at the PAM4 receiver to decode the received signal and recover the transmitted PAM4 symbols. It addresses the effects of noise, channel impairments, and inter-symbol interference (ISI) that are common in high-speed communication channels.

In PAM4 (and other modulation schemes), MLSE incorporates DFE tap values as part of its CSI. DFE taps are coefficients used to adjust feedback in a DFE equalizer, helping to cancel ISI caused by the communication channel. DFE taps control how much of the previously detected symbols are subtracted from the current sample to remove ISI. These taps (e.g., the values of the coefficients of the taps, without limitation) may be dynamically adjusted, including during an equalization process, to enhance performance based on channel conditions. In MLSE, DFE tap values (which represent the feedback coefficients that control the taps, and thus the amount of feedback being applied) may be used as parameters when determining the most likely transmitted sequence.

Traditional PAM4 MLSE uses a 4:4 trellis structure to track and decode transmitted symbols. The 4:4 trellis structure maintains four distinct states representing the four possible PAM4 signal levels (0, 1, 2, 3) utilized to represent symbols, considering 16 transitions (4 possible transitions per state). Each state corresponds to a specific level of the received signal, and MLSE keeps track of the possible transitions between these states over time.

MLSE uses the trellis structure to decode the received PAM4 symbols accurately. The four states represent the four possible values that a transmitted symbol can take. At each symbol interval, the receiver must decide which of the four possible states the received symbol corresponds to. At each symbol interval, each state can transition to any of the four states, resulting in 16 possible transitions (4 previous states×4 current states). This decision is based on minimizing the accumulated error (or distance) from the expected signal pattern.

Each state transition has an associated score based on how well the received signal matches the expected signal for that transition. The survivor path is the sequence of previous states that led to the current state with the minimum cumulative error.

The trellis structure helps the receiver handle ISI and noise by considering all possible sequences of states (paths) that could lead to the current received symbol. By evaluating the cumulative error along these paths, the MLSE can determine the most likely sequence of transmitted symbols that resulted in the observed received signal. In traditional MLSE, the MLSE algorithm evaluates all 16 possible transitions and updates the scores and survivor paths for each state. The state with the lowest cumulative score at the current symbol interval is considered the most likely state, and its survivor path represents the most likely sequence of transmitted symbols.

Initializing a trellis of an MLSE engine is the process of setting its state to represent the memory of a communication channel. When a trellis-based decoder begins decoding in an uninitialized state (i.e., a cold start), it lacks knowledge of the past symbols that affected the current state of the communication channel, which the trellis represents. As a result, the trellis-based decoder might select a transmitted sequence that is different from the sequence it would choose with full or partial knowledge of the channel's memory.

To reduce undesirable effects of a cold start, run-up (RU) symbols may be provided to the decoder before an actual received sequence of symbols. RU symbols are a sequence of symbols designed to reflect characteristics of a communication channel (e.g., properties such as modulation scheme or typical interference patterns, without limitation) to ensure the channel's memory as represented by the trellis is set based on those characteristics. Processing the RU symbols allows the decoder to explore the trellis and arrive at a state that better (e.g., more closely, without limitation) reflects the channel's memory. Once the trellis is initialized using the RU symbols, the decoder may begin decoding a received sequence with a state more representative of actual channel conditions.

Traditionally, initializing a trellis utilizing RU symbols takes multiple clock cycles as the decoder explores the trills using the RU symbols. The inventor of this disclosure appreciates that reducing the time to initialize a trellis based on RU symbols could reduce decoding latency (i.e., the time to decode a sequence of symbols), average decoding latency (i.e., the average (mean) time to decode multiple sequences of symbols over multiple iterations), or both, respectively of a decoder.

One or more examples relate, generally, to initializing a trellis (e.g., of a trellis-based decoder, without limitation) utilizing predetermined state information. In one or more examples, a trellis is initialized by setting its state at least partially based on predetermined state information. In one or more examples, such an initialized trellis may be utilized to decode a received sequence. Alternatively, such an initialized trellis may be further initialized utilizing one or more RU symbols and the further initialized trellis may be utilized to decode a received sequence.

In one or more examples, the predetermined state information may be at least partially based on simulations (e.g., computer-based simulation, without limitation) utilizing simulation data that includes sequences of RU symbols. In one or more examples, the simulations may account for channel characteristics or decision feedback equalizer (DFE) tap configurations. As a non-limiting example, simulation parameters for respective simulations may be at least partially based on one or more of: specific channel characteristics or decision feedback equalization (DFE) tap configurations (e.g., a DFE tap value, without limitation). In this manner, predetermined state information utilized to initialize a trellis-based decoder may be at least partially based on a similar channel, similar DFE tap configurations, or both.

In one or more examples, initialization of a trellis is simulated for respective permutations of the RU symbols and the resultant state information is stored for respective permutations of the RU symbols.

In one or more examples, initialization of a trellis may be simulated multiple times for respective permutations of the RU symbols, respective resultant state information averaged, and average resultant state information is stored as the predetermined state information for respective permutations of the RU symbols.

In one or more examples, initialization of a trellis may be simulated multiple times for respective permutations of the RU symbols, median respective resultant state information is selected, and median resultant state information is stored as the predetermined state information for respective permutations of the RU symbols.

In one or more examples, a sets of predetermined state information may be stored in memory, as a non-limiting example, in array, table, or other data structure. In one or more examples, a set of predetermined state information may include permutations of RU symbols and associated predetermined state information.

In one or more examples, a look-up-table (LUT) (also referred to herein as a “startup LUT”) may be utilized to associate respective permutations of RU symbols and predetermined state information of respective sets. In one or more examples, permutations of RU symbols may be utilized as an index of the LUT and the associated predetermined state information as values at the indexes. In one or more examples, portions of the permutations of RU symbols may be utilized as an index to the LUT. As a non-limiting example, some number (e.g., 1, 2, 3, 4, without limitation) of respective most-significant bits (MSBs) of respective symbols of respective permutation of RU symbols may be combined to form an index for the LUT. Thus, for a given sequence of RU symbols, the MSBs may combined to form a key and the key utilized to search the LUT.

One or more examples relate, generally, to a decoder that initializes a trellis utilizing predetermined state information. The decoder may have, or access, sets of predetermined state information. The decoder may initialize the trellis by setting a state of a trellis at least partially based on the set of predetermined state information and a sequence of RU symbols (e.g., utilizing a portion of a sequence of RU symbols, portions of respective RU symbols of a sequence of RU symbols, without limitation). Upon initializing the trellis, the decoder utilizes the initialized trellis to decode a received sequence.

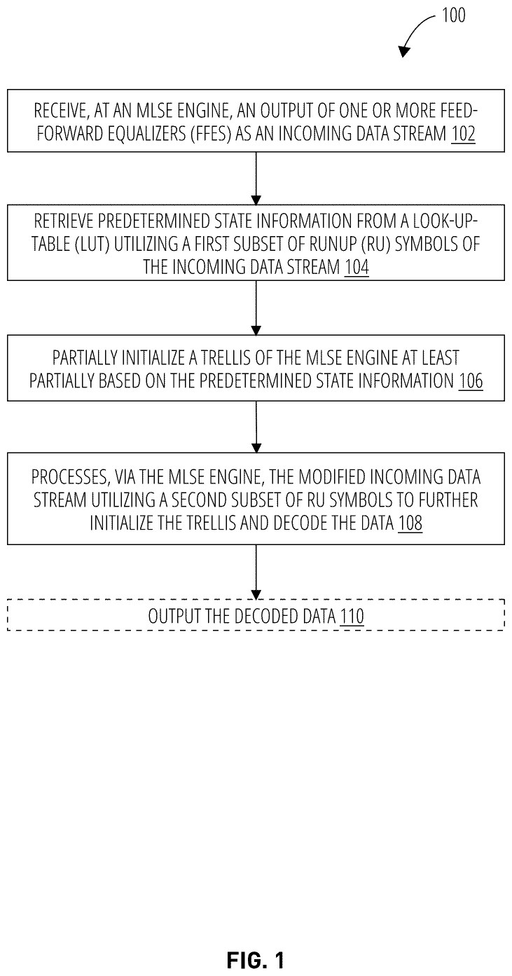

FIG. 1 illustrates an example process 100 according to a general method to initialize a trellis, in accordance with one or more examples. Although the example process 100 depicts a particular sequence of operations, the sequence may be altered without departing from the scope of the present disclosure. For example, some of the operations depicted may be performed in parallel or in a different sequence that does not materially affect the function of the process 100. In other examples, different components of an example device or system that implements the process 100 may perform functions at substantially the same time or in a specific sequence. In one or more examples, some or a totality of operations of process 100 may be performed pipeline architecture 200 or functional blocks of process 300, as discussed below.

According to one or more examples, process 100 may include receiving, at an MLSE engine, an output of one or more feed-forward equalizer (FFEs) as an incoming data stream at operation 102. An FFE works by applying a filter to an incoming signal, effectively predicting, and canceling out the effects of ISI (equalizing) based on known characteristics of the channel. After the equalization process, the FFE generates an output signal (an FFE output). In one or more examples, the FFE output may include symbols that represent modulated data (e.g., PAM4 symbols in a high-speed SerDes link, without limitation). This output is a stream of FFE processed data, where at least some of the intersymbol interference has been mitigated. However, the FFE output still requires further processing by one or more MLSE engines to fully decode transmitted data.

The MLSE engine receives the output of the FFE as the incoming data stream. The data stream consists of symbols that have already been processed by the one or more FFEs but have not yet been fully decoded into their original transmitted form. The incoming data stream may include decode symbols, run-up symbols, and rundown symbols as discussed below. The mapping of the FFE output to these symbols may be implemented through specific signal routing between the outputs of the one or more FFEs and the inputs of the MLSE engine.

According to one or more examples, process 100 may include retrieving predetermined state information from a Look-Up-Table (LUT) utilizing a first subset of run-up symbols of the incoming data stream, at operation 104. The LUT is a precomputed table that stores predetermined state information associated with the first subset of RU symbols. Instead of recalculating complex operations every time they are needed, a LUT allows the system to retrieve precomputed results based on a given input. In this context, the LUT is used to store predetermined state information useable to initialize the trellis of the MLSE engine.

Run-up (RU) symbols are symbols that are sent to the MLSE engine before (in sequential order) the decode data to help initialize the trellis of the MLSE engine to reflect the channel's memory (such as intersymbol interference, or ISI). These symbols represent the known portion of the data and carry information about the channel's memory. RU symbols allow the MLSE decoder to set its initial state by “warming up” the trellis to match the characteristics of the channel, which allows for accurate decoding of the incoming data.

In one or more examples, the LUT includes precomputed state information for the MLSE trellis. In one or more examples, the predetermined state information may be calculated offline using simulations or models of the communication channel. Storing predetermined state information with the LUT reduces the complexity of the system to dynamically compute the initial trellis state each cycle. In one or more examples, the first subset of RU symbols are a portion of the RU symbols selected for the MLSE engine. The first subset of RU symbols are utilized as the index to retrieve the predetermined state information from the LUT.

In one or more examples, the predetermined state information may be scores for respective states of the trellis of the MLSE engine. For example, in the case of a four (4) state trellis, four scores are retrieved from the LUT based on the first subset of RU symbols. In one or more examples, the entire first subset of RU symbols may be utilized as the index. Additionally or alternatively, in one or more examples, portions of the RU symbols (e.g., most-significant-bits, least-significant bits, or others, without limitation) may be utilized as the index to retrieve the predetermined state information.

According to one or more examples, process 100 may include partially initializing the trellis of the MLSE engine at least partially based on the predetermined state information at operation 106. The trellis is a state diagram that represents possible sequences of symbols in a communication channel over time. The MLSE engine uses this trellis to calculate the likelihood of different possible transmitted sequences and then selects one sequence be the decoder output. The predetermined state information provides scores that represent the initial state metrics or state probabilities for the trellis, allowing it to start the decoding process from a known, at least partially initialized state.

The MLSE engine may process the remaining RU symbols of the incoming data stream (a second subset of RU symbols that is different that the first subset) utilizing the partially initialized trellis to finish initializing the trellis and decode the decode symbols.

According to one or more examples, process 100 may include processes, via the MLSE engine, the modified incoming data stream (the original incoming data stream less the first subset of RU symbols), utilizing the second subset of RU symbols to further initialize the trellis and decode the data at operation 108. The MLSE engine uses the reduced set of RU symbols that were introduced and processed in operation 108. These symbols help the decoder fully initialize the trellis, ensuring that it starts decoding the actual data from a well-established state.

According to one or more examples, process 100 may optionally include output the decoded data at operation 110.

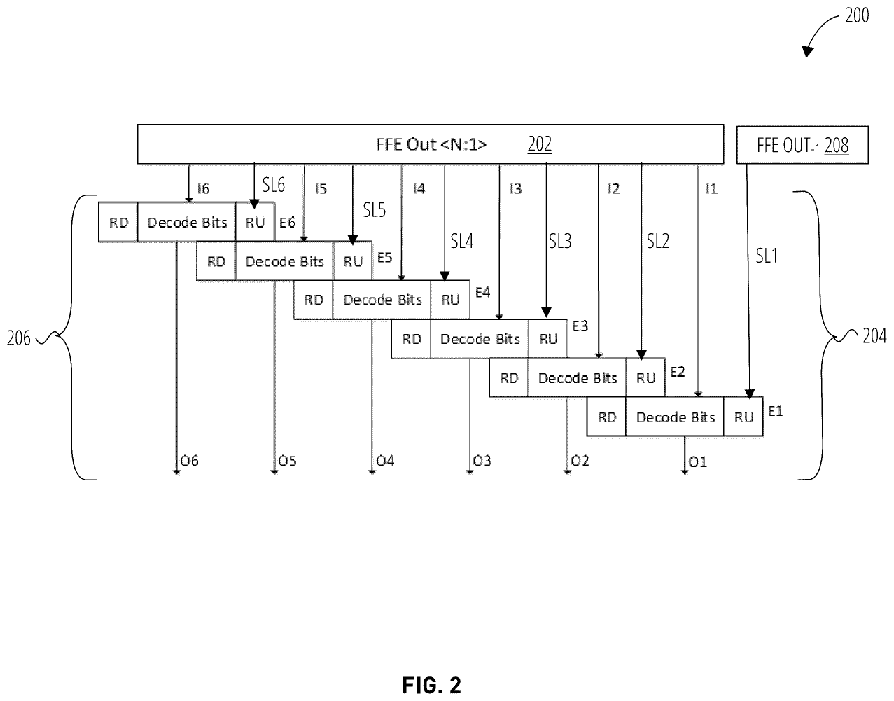

FIG. 2 is a block diagram depicting a pipeline architecture 200 of a windowed MLSE process that utilizes predetermined state information to at least partially initialize a trellis of an MLSE engine, in accordance with one or more examples.

Pipeline architecture 200 includes feed-forward equalizer (FFE) output 202 and windowed MLSE engines 204. Feed-forward equalizer output 202 represents the output from a feed-forward equalizer (FFE not depicted), feeding into different windowed MLSE engines 204, and more specifically into respective MSLE engines E1, E2, E3, E4, E5 and E6. Portions of the feed-forward equalizer output 202 are fed to the windowed MLSE engines 204 via startup LUTs SL1, SL2, SL3, SL4, SL5 and SL6. As discussed, below, respective trellis's of the windowed MLSE engines 204 E1 to E6 are at least partially initialized by the startup LUTs SL1-SL6. Since the trellis's are partially initialized, fewer RU symbols are utilized to finish initializing the trellis, which reduces the number of RU symbols in respective windows ILI to IL6 and in the windowed incoming data as a whole. As discussed below, the number of MLSE engines required to process windowed incoming data depends on the number of RU symbols, thus, if fewer RU symbols are utilized in the windowed incoming data then fewer MLSE engines are required as compared to traditional MLSE.

The notation <N: 1>indicates that the FFE output consists of N symbols denoted symbol 1 to symbol N. Sets of those symbols I1, I2, I3, I4, I5, and I6 (referred to as “a window”) are fed to respective MLSE engines E1 to E6 of the windowed MLSE engines 204. Respective MLSE engines E1 to E6 process the respective windows.

Respective windows include a RU symbols, D symbols (or bits), and RD symbols. The mapping of FFE Out <N:1> to these symbols may be implemented through specific signal routing between the outputs of the one or more FFEs and the inputs of the MLSE engine. RU symbols are utilized by the respective Windowed MLSE engines 204 to initialize its trellis. D symbols are processed by the MLSE engine utilizing the initialized trellis. RD symbols are utilized by the MLSE engine to close the trellis (i.e., for the given portion of incoming data stream portions 206).

The set of RU symbols may include a first subset of RU symbols that are fed to a startup LUT (SL1 to SL6) to partially initialize trellises of the MLSE engines E1 to E6, and a second subset of RU symbols that are fed directly to the RU input of the MLSE engines E1 to E6. Notably, the startup LUT SL1 utilized to initialize the trellis of MLSE engine E1 is fed RU symbols from the output of the FFE for a previous (e.g., earlier in time, without limitation) cycle, FFE Out₋₁ 208.

Notably, a respective MLSE engine processes P symbols of a respective FFE Out <N:1>per clock cycle, where P is an integer >0. The number E of MLSE engines required to process the output of an FFE is given by Equation 1, where “ceil” is a ceiling function, and RU, RD and D represent the number of respective RD symbols, RU symbols, and Decode bits:

E=ceil (N/P*(RD+RU+D)/D) [Equation 1]

So, the number E of MLSE engines required to process the output of an FFE depends on the number of RU symbols. Reducing the number of RU symbols as compared to traditional MLSE reduces the number of MLSE engines.

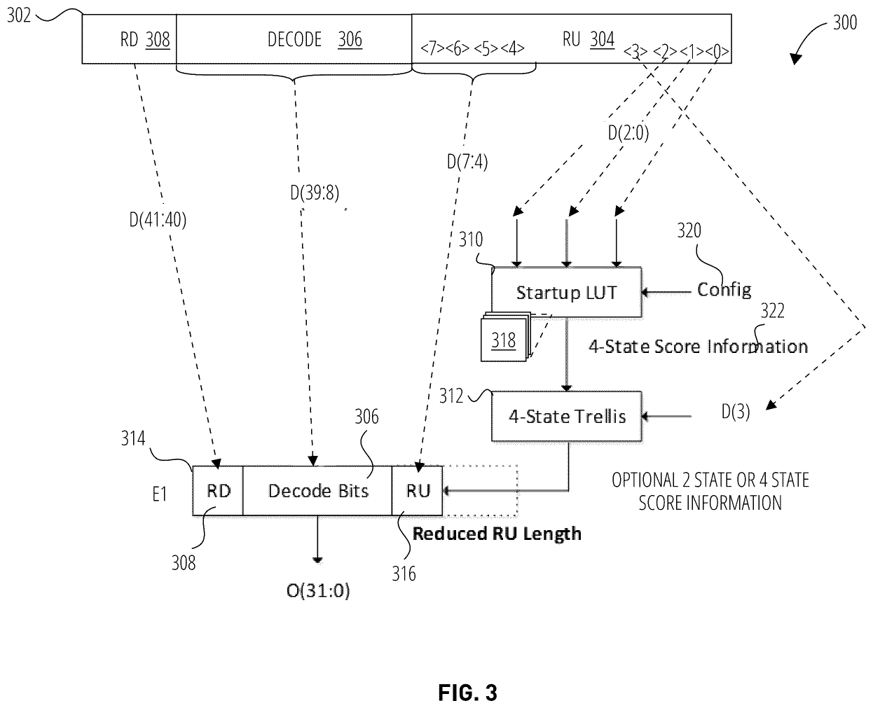

FIG. 3 is a functional block diagram of a pipeline architecture depicting a process 300 to initialize a trellis of an MLSE engine, in accordance with one or more examples.

More specifically, the trellis is partially initialized utilizing predetermined state information retrieved from a LUT utilizing a first subset of RU symbols as an index. The partially initialized trellis is further initialized by the MLSE engine utilizing a second subset of RU symbols and the data decoded by the MLSE engine utilizing the fully initialized trellis.

The pipeline architecture of FIG. 3 includes window 302, startup LUT 310, 4-state trellis 312, and modified window 314.

The process begins with a window 302 being received (e.g., from an FFE). The window 302 includes RU symbols 304, decode symbols 306, and RD symbols 308. RU symbols 304 includes the symbols in positions <0> to <7> of the window 302. Decode symbols 306 include symbols in positions <8> to <39> of window 302. RD symbols 308 include symbols position <40> and <41> of window 302. The position number corresponds to the order of symbol reception (e.g., at a receiver, without limitation).

A first subset of RU symbols in positions <0> to <3>, D(3:0), are utilized to at least partially initialize 4-state trellis 312. A second subset of RU symbols in positions <4> to <7>, D(7:4), are fed to the RU inputs of MLSE engine E1 for processing.

RU symbols D(2:0) are fed to the startup LUT 310 and utilized to retrieve state score information 322, which in turn is used to set a state of 4-state trellis 312. The startup LUT 310 is pre-configured with a set of predetermined state information 318 based on a configuration signal 320 (“Config”). Startup LUT 310 is pre-configured with predetermined state information 318 that associates these previous symbols to a score that can help initialize 4-state trellis 312. These associations and predetermined state information 318 are computed offline, for example, using simulations, to reflect the behavior of the channel under different conditions. The predetermined state information 318 may include score information that represents the likelihood of the decoder being in respective ones of the possible states of the trellis. The higher the score, the more likely the trellis is in that state at a given time.

In response to receipt of the respective symbols of RU symbols 304, the startup LUT 310 outputs state score information 322. The state score information 322 includes four (4) state scores, one state score per PAM4 level. The 4-state trellis 312 is initialized using this predetermined state information 318 including the four state scores. These scores are utilized to set the initial state metrics for each of the four possible states of 4-state trellis 312.

The RU symbol in position <3> is fed to the MLSE engine E1, which processes it utilizing the partially initialized 4-state trellis 312 to further propagate the state of 4-state trellis 312 before processing modified window 314 that includes the second subset of RU symbols 316. RU symbol D(3) serves as that final known input, helping to make a final adjustment to the 4-state trellis 312 before the actual data sequence begins decoding.

When the MLSE engine E1 processes the modified window 314, it uses the second subset of RU symbols 316 to further initialize the 4-state trellis 312 that was partially initialized utilizing state score information 322 from the Startup LUT 310 and RU symbol D (3). The 4-state trellis 312 is then fully initialized before being utilized by modified window 314 to decode the actual data symbols.

In some cases, fewer than all of the available states of the 4-state trellis 312 may be retained to represent its state each cycle, for example, because, based on the specific application, some states are not needed. Thus, optionally, the 4-state score information may be reduced to 2-state score information to reduce memory used and utilized to set the subset of states of the 4-state trellis 312 being utilized.

This processing takes place with a reduced run-up length meaning fewer RU symbols are used than in the standard configuration. After processing, the output O(31:0) is produced from the MLSE engine, flowing through the decode symbols 306 D(39:8). The RD symbols 308 and second subset of RU symbols 316 of modified window 314 are used to initialize and finalize the 4-state trellis 312 and are not part of the output.

By using a reduced run-up configuration, latency is reduced while still ensuring the trellis state is properly initialized for accurate decoding. The number of RU symbols used may vary based on operating conditions or system requirements, such as specific channel memory lengths or memory optimizations. As a non-limiting example, smaller memory may be utilized to store 2-state score information than 4-state score information.

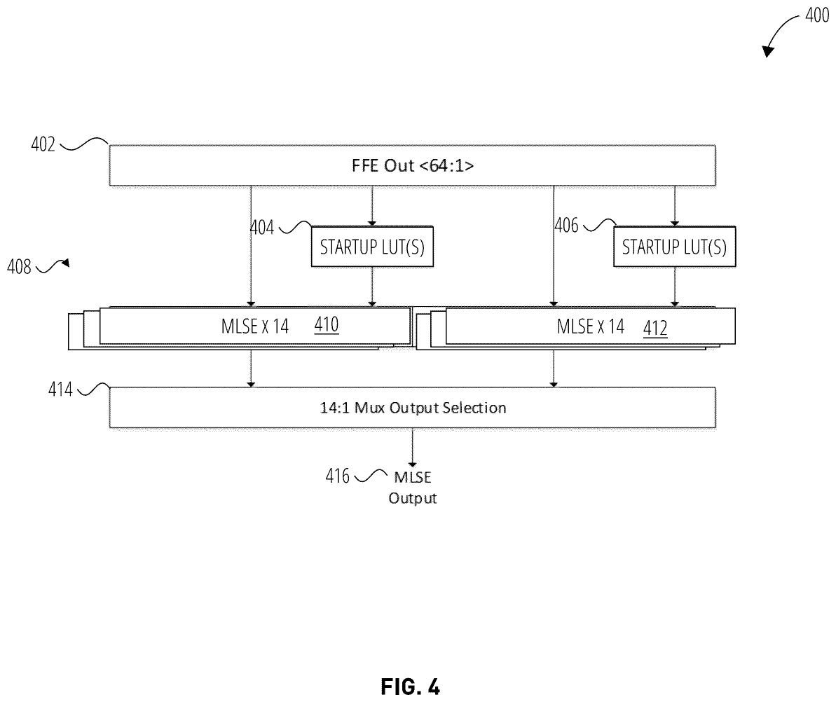

FIG. 4 is a block diagram depicting pipeline architecture 400 of a decoder that utilizes predetermined state information to at least partially initialize a trellis of an MLSE engine before decoding a received sequence of symbols, in accordance with one or more examples.

FFE output 402 represents the output from an FFE (FFE not depicted) with 64 parallel outputs. This is the input signal that is processed by the downstream MLSE engines 408. The purpose of the FFE is to mitigate intersymbol interference (ISI) before the data is passed to the MLSE decoders for further processing. The 64:1 notation indicates that the FFE output 402 has 64 parallel streams that are reduced as the data is processed by the system.

Startup LUT 404 and startup LUT 406 are responsible for providing predetermined state information to initialize the trellis states of the corresponding MLSE engines. The startup LUTs include look-up tables (LUTs), which hold precomputed entries of scores, as a non-limiting example, based on previous simulations of the trellis and channel conditions. In some examples, the LUTs use bits from combinations of RU symbols (e.g., the first subset of RU symbols of FIG. 3, without limitation) as an index to retrieve the scores utilized to set initial states of the trellises.

In the specific non-limiting example depicted by FIG. 4, MLSE engine 410 and MLSE engine 412 each represent stacks of fourteen (14) MLSE engines utilized in windowed MLSE. These engines process FFE Out <64:1> signal using the state information provided by the Startup LUTs (startup LUT 404 and startup LUT 406).

By way of non-limiting example of a contemplated operation of pipeline architecture 400, when 64 symbols are output by FFE output 402, two MSLE engines start up, one from MLSE engine 410 and one from MLSE engine 412, and they each reeve a window of 42 symbols consisting of eight (8) RU symbols, two (2) RD symbols, and thirty-two (32) decode symbols. The two selected MLSE engines process their respective windows as discussed above. Next cycle, another 64 symbols are output by FFE output 402 and two more MLSE engines start up, one from MLSE engine 410 and one from MLSE engine 412, and they each reeve a window of 42 symbols to process. Up to fourteen pairs of MLSE engines selected from MLSE engine 410 and MLSE engine 412 may be running at a time.

The 14:1 MUX Output Selection block (MUX output selection 414) selects (selection signal not shown) the output from one of the 14 MLSE engines from each stack (i.e., from blocks MLSE engines 408 and MLSE engine 410) to produce the MLSE output 416.

The MUX of MUX output selection 414 combines the parallel outputs from the MLSE engines MLSE engine 410 and MLSE engine 412 into a single output stream for further processing or transmission. This is part of the pipeline architecture, ensuring efficient and synchronized data flow.

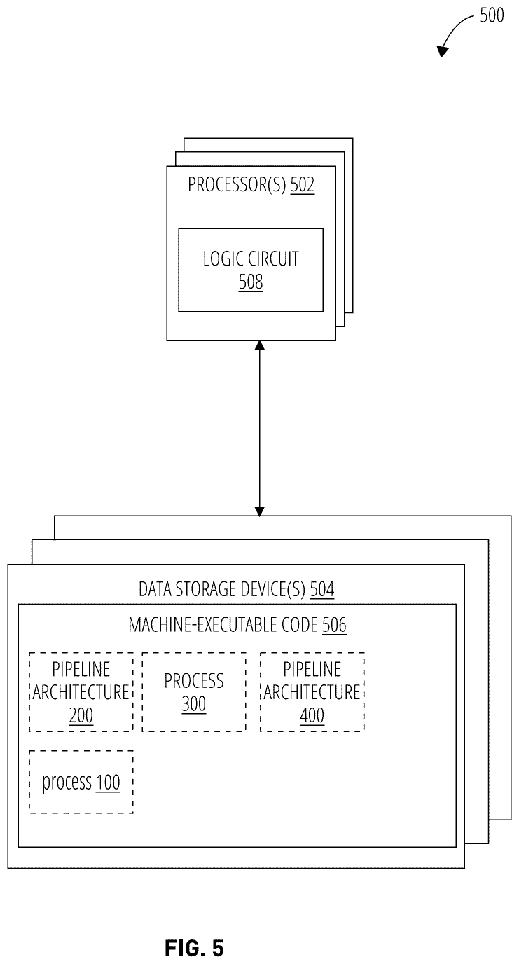

It will be appreciated by those of ordinary skill in the art that functional elements of examples disclosed herein (e.g., functions, operations, acts, processes, or methods) may be implemented in any suitable hardware, software, firmware, or combinations thereof. FIG. 5 illustrates non-limiting examples of implementations of functional elements disclosed herein. In some examples, some or all portions of the functional elements disclosed herein may be performed by hardware capable of carrying out the functional elements.

FIG. 5 is a block diagram of a circuitry 500 that, in some examples, may be used to implement various functions, operations, acts, processes, or methods disclosed herein. The circuitry 500 includes one or more processors 502 (sometimes referred to herein as “processors 502”) operably coupled to one or more data storage devices 504 (sometimes referred to herein as “storage 504”). The storage 504 includes machine-executable code 506 stored thereon and the processors 502 include logic circuit 508. The machine-executable code 506 information describing functional elements that may be implemented by (e.g., performed by) the logic circuit 508. The logic circuit 508 is adapted to implement (e.g., perform) the functional elements described by the machine-executable code 506. The circuitry 500, when executing the functional elements described by the machine-executable code 506, should be considered as special purpose hardware for carrying out functional elements disclosed herein. In some examples, the processors 502 may perform the functional elements described by the machine-executable code 506 sequentially, concurrently (e.g., on one or more different hardware platforms), or in one or more parallel process streams.

When implemented by logic circuit 508 of the processors 502, the machine-executable code 506 adapts the processors 502 to perform operations of examples disclosed herein. By way of non-limiting example, the machine-executable code 506 may adapt the processors 502 to perform some or a totality of operations discussed herein, for example, associated with process 100, pipeline architecture 200, process 300 or pipeline architecture 400.

Also by way of non-limiting example, the machine-executable code 506 may adapt the processors 502 to perform some or a totality of features, functions, or operations disclosed herein. More specifically, features, functions, or operations disclosed herein for one or more of: process 100, pipeline architecture 200, process 300, or pipeline architecture 400.

The processors 502 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer executes functional elements corresponding to the machine-executable code 506 (e.g., software code, firmware code, hardware descriptions) related to examples of the present disclosure. It is noted that a general-purpose processor (may also be referred to herein as a host processor or simply a host) may be a microprocessor, but in the alternative, the processors 502 may include any conventional processor, controller, microcontroller, or state machine. The processors 502 may also be implemented as a combination of computing devices, such as a combination of a DSP and a microprocessor, a plurality of microprocessors, one or more microprocessors in conjunction with a DSP core, or any other such configuration.

In some examples, the storage 504 includes volatile data storage (e.g., random-access memory (RAM)), non-volatile data storage (e.g., Flash memory, a hard disc drive, a solid state drive, erasable programmable read-only memory (EPROM), without limitation). In some examples, the processors 502 and the storage 504 may be implemented into a single device (e.g., a semiconductor device product, a system on chip (SOC), without limitation). In some examples, the processors 502 and the storage 504 may be implemented into separate devices.

In some examples, the machine-executable code 506 may include computer-readable instructions (e.g., software code, firmware code). By way of non-limiting example, the computer-readable instructions may be stored by the storage 504, accessed directly by the processors 502, and executed by the processors 502 using at least the logic circuit 508. Also by way of non-limiting example, the computer-readable instructions may be stored on the storage 504, transferred to a memory device (not shown) for execution, and executed by the processors 502 using at least the logic circuit 508. Accordingly, in some examples, the logic circuit 508 includes electrically configurable logic circuit 508.

In some examples, the machine-executable code 506 may describe hardware (e.g., circuitry) to be implemented in the logic circuit 508 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, Verilog, System Verilog or very large scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 508 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples, the machine-executable code 506 may include an HDL, an RTL, a GL description, a mask level description, other hardware description, or any combination thereof.

In examples where the machine-executable code 506 includes a hardware description (at any level of abstraction), a system (not shown, but including the storage 504) implements the hardware description described by the machine-executable code 506. By way of non-limiting example, the processors 502 may include a programmable logic device (e.g., an FPGA or a PLC) and the logic circuit 508 may be electrically controlled to implement circuitry corresponding to the hardware description into the logic circuit 508. Also by way of non-limiting example, the logic circuit 508 may include hard-wired logic manufactured by a manufacturing system (not shown, but including the storage 504) according to the hardware description of the machine-executable code 506.

Regardless of whether the machine-executable code 506 includes computer-readable instructions or a hardware description, the logic circuit 508 is adapted to perform the functional elements described by the machine-executable code 506 when implementing the functional elements of the machine-executable code 506. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, without limitation) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means “some or a totality.” As used herein, the term “each and every” means a “totality.”

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples include:

Example 1: A method, comprising: at least partially initializing a trellis of an MLSE engine at least partially based on predetermined state information about a communication channel associated with an incoming data stream; and processing, via the MLSE engine, the incoming data stream to further initialize the trellis and decode the incoming data stream.

Example 2: The method according to Example 1, wherein the trellis is a multi-state trellis that represents signal levels of a modulation scheme.

Example 3: The method according to any of Examples 1 and 2, wherein the modulation scheme is PAM4 or NRZ.

Example 4: The method according to any of Examples 1 through 3, wherein the predetermined state information comprises scores that represent likelihoods of the trellis being in respective ones of possible states of the trellis.

Example 5: The method according to any of Examples 1 through 4, comprising: looking up the scores at least partially based on a subset of run-up symbols in the incoming data stream.

Example 6: The method according to any of Examples 1 through 5, wherein reducing the subset of run-up symbols in the incoming data stream comprises deleting the subset of run-up symbols from the incoming data stream.

Example 7: The method according to any of Examples 1 through 6, comprising: combining most-significant bits of the subset of run-up symbols in the incoming data stream; and looking up the scores at least partially based on the combined most-significant bits.

Example 8: The method according to any of Examples 1 through 7, wherein the scores are based on simulations, wherein the simulations considered one or more of: specific channel characteristics or decision feedback equalization (DFE) tap configurations.

Example 9: The method according to any of Examples 1 through 8, wherein partially initializing the trellis of the MLSE engine at least partially based on predetermined state information about the communication channel associated with the incoming data stream comprises: directly utilizing at least one run-up symbol of the incoming data stream to initialize the trellis.

Example 10: The method according to any of Examples 1 through 9, wherein processing the incoming data stream to further initialize the trellis and decode the incoming data stream comprises: processing a window of the incoming data stream to further initialize the trellis and decode the incoming data stream.

Example 11: An apparatus, comprising: a LUT to store predetermined state information about a communication channel associated with an incoming data stream; a startup engine to: at least partially initialize a trellis based on respective predetermined state information retrieved from the LUT; and partially initializing a trellis of an MLSE engine at least partially based on predetermined state information about a communication channel associated with an incoming data stream; and an MLSE engine to process the incoming data stream to further initialize the trellis and decode the incoming data stream.

Example 12: The apparatus according to Example 11, wherein the trellis is a multi-state trellis that represents signal levels of a modulation scheme.

Example 13: The apparatus according to any of Examples 11 and 12, wherein the modulation scheme is PAM4 or NRZ.

Example 14: The apparatus according to any of Examples 11 through 13, wherein the startup engine to directly utilize at least one run-up symbol of the incoming data stream to initialize the trellis.

Example 15: The apparatus according to any of Examples 11 through 14, wherein the predetermined state information stored at the LUT includes scores that represent likelihoods of the trellis being in respective ones of possible states of the trellis.

Example 16: The apparatus according to any of Examples 11 through 15, wherein the scores are based on simulations, wherein the simulations considered one or more of: specific channel characteristics or decision feedback equalization (DFE) tap configurations.

Example 17: The apparatus according to any of Examples 11 through 16, wherein the scores are indexed at the LUT based on run-up symbols.

Example 18: The apparatus according to any of Examples 11 through 17, wherein the scores are indexed based on bits that correspond to a combination of most-significant-bits of run-up symbols.

Example 19: The apparatus according to any of Examples 11 through 18, wherein the startup engine to reduce a set of run-up symbols in the incoming data stream by deleting a subset of run-up symbols from the incoming data stream.

Example 20: The apparatus according to any of Examples 11 through 19, wherein the MLSE engine to process a window of the incoming data stream.

Example 21: An apparatus, comprising: an input to receive an incoming data stream; at least one processor; and a memory to store instructions that, responsive to execution by the at least one processor, enable the at least one processor to: at least partially initialize a trellis for MLSE at least partially based on predetermined state information about a communication channel associated with an incoming data stream; and process the incoming data stream to further initialize the trellis and decode the incoming data stream.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. A method, comprising:
at least partially initializing a trellis of an MLSE engine at least partially based on predetermined state information about a communication channel associated with an incoming data stream; and
processing, via the MLSE engine, the incoming data stream to further initialize the trellis and decode the incoming data stream.

2. The method of claim 1, wherein the trellis is a multi-state trellis that represents signal levels of a modulation scheme.

3. The method of claim 2, where in the modulation scheme is PAM4 or NRZ.

4. The method of claim 1, wherein the predetermined state information comprises scores that represent likelihoods of the trellis being in respective ones of possible states of the trellis.

5. The method of claim 4, comprising:
looking up the scores at least partially based on a subset of run-up symbols in the incoming data stream.

6. The method of claim 5, wherein reducing the subset of run-up symbols in the incoming data stream comprises deleting the subset of run-up symbols from the incoming data stream.

7. The method of claim 5, comprising:
combining most-significant bits of the subset of run-up symbols in the incoming data stream; and looking up the scores at least partially based on the combined most-significant bits.

8. The method of claim 4, wherein the scores are based on simulations, wherein the simulations considered one or more of: specific channel characteristics or decision feedback equalization (DFE) tap configurations.

9. The method of claim 1, wherein partially initializing the trellis of the MLSE engine at least partially based on predetermined state information about the communication channel associated with the incoming data stream comprises:
directly utilizing at least one run-up symbol of the incoming data stream to initialize the trellis.

10. The method of claim 1, wherein processing the incoming data stream to further initialize the trellis and decode the incoming data stream comprises:
processing a window of the incoming data stream to further initialize the trellis and decode the incoming data stream.

11. An apparatus, comprising:
a LUT to store predetermined state information about a communication channel associated with an incoming data stream;
a startup engine to:
at least partially initialize a trellis based on respective predetermined state information retrieved from the LUT; and
partially initializing a trellis of an MLSE engine at least partially based on predetermined state information about a communication channel associated with an incoming data stream; and
an MLSE engine to process the incoming data stream to further initialize the trellis and decode the incoming data stream.

12. The apparatus of claim 11, wherein the trellis is a multi-state trellis that represents signal levels of a modulation scheme.

13. The apparatus of claim 12, wherein the modulation scheme is PAM4 or NRZ.

14. The apparatus of claim 11, wherein the startup engine to directly utilize at least one run-up symbol of the incoming data stream to initialize the trellis.

15. The apparatus of claim 11, wherein the predetermined state information stored at the LUT includes scores that represent likelihoods of the trellis being in respective ones of possible states of the trellis.

16. The apparatus of claim 15, wherein the scores are based on simulations, wherein the simulations considered one or more of: specific channel characteristics or decision feedback equalization (DFE) tap configurations.

17. The apparatus of claim 15, wherein the scores are indexed at the LUT based on run-up symbols.

18. The apparatus of claim 15, wherein the scores are indexed based on bits that correspond to a combination of most-significant-bits of run-up symbols.

19. The apparatus of claim 11, wherein the startup engine to reduce a set of run-up symbols in the incoming data stream by deleting a subset of run-up symbols from the incoming data stream.

20. The apparatus of claim 11, wherein the MLSE engine to process a window of the incoming data stream.

21. An apparatus, comprising:
an input to receive an incoming data stream;
at least one processor; and
a memory to store instructions that, responsive to execution by the at least one processor, enable the at least one processor to:
at least partially initialize a trellis for MLSE at least partially based on predetermined state information about a communication channel associated with an incoming data stream; and
process the incoming data stream to further initialize the trellis and decode the incoming data stream.
